(19) United States
(12) Patent Application Publication
(10) Pub. No.: US 2022/0043027 A1
(43) Pub. Date: Feb. 10, 2022

(54) PROBE MODULE HAVING MICROELECTROMECHANICAL PROBE AND METHOD OF MANUFACTURING THE SAME

(71) Applicant: MPI CORPORATION, Chu-Pei City (TW)

(72) Inventors: Yu-Chen HSU, Chu-Pei City (TW); Bang-Shun LIU, Chu-Pei City (TW); Ming-Ta HSU, Chu-Pei City (TW); Fuh-Chyun TANG, Chu-Pei City (TW); Shao-Lun WEI, Chu-Pei City (TW); Ya-Fan KU, Chu-Pei City (TW); Yu-Wen WANG, Chu-Pei City (TW)

(73) Assignee: MPI CORPORATION, Chu-Pei City (TW)

(21) Appl. No.: 17/506,173

(22) Filed: Oct. 20, 2021

Related U.S. Application Data
(63) Continuation of application No. 16/596,087, filed on Oct. 8, 2019.
(60) Provisional application No. 62/744,661, filed on Oct. 12, 2018.

(30) Foreign Application Priority Data
Apr. 26, 2019 (TW) 108114724

(51) Int. Cl. G01R 1/067; G01R 1/073; B81C 1/00

(52) U.S. Cl. CPC G01R 1/06744; G01R 1/07342; B81C 2201/0143; B81C 1/00111; G01R 1/0675; B81C 1/0015

(57) ABSTRACT

A probe module includes a circuit board and at least one probe formed on a probe installation surface of the circuit board by a microelectromechanical manufacturing process and including a probe body and a probe tip. The probe body includes first and second end portions and a longitudinal portion having first and second surfaces facing toward opposite first and second directions. The probe tip extends from the probe body toward the first direction and is processed with a gradually narrowing shape by laser cutting. The first and/or second end portion has a supporting seat protruding from the second surface toward the second direction and connected to the probe installation surface, such that the longitudinal portion and the probe tip are suspended above the probe installation surface. The probe has a tiny pinpoint for detecting tiny electronic components, and its manufacturing method is time-saving and high in yield rate.

### CROSS-REFERENCE TO RELATED APPLICATION

This application is a Continuation of application Ser. No. 16/596,087, filed Oct. 8, 2019, which claims priority under 35 USC 119(e) to U.S. Provisional Application No. 62/744,662 filed on Oct. 8, 2019, and under 35 U.S.C. § 119(a) to Patent Application No. 108114724, filed in Taiwan on Apr. 26, 2019, all of which are hereby expressly incorporated by reference into the present application.

### BACKGROUND OF THE INVENTION

### 1. Field of the Invention

The present invention relates generally to probe modules of probe cards and more particularly, to a probe module having a microelectromechanical probe and a method of manufacturing the probe module.

### 2. Description of the Related Art

The conventional probes of probe cards can be primarily classified according to the shape thereof into two types, including vertical probes and cantilever probes. These two types of probes can be further classified according to the manufacturing method thereof into two types, including traditional probes processed by machining and microelectromechanical probes made by a microelectromechanical manufacturing process. However, for the smaller and smaller electronic components of nowadays, the conductive pads thereof have tiny size and intervals, so their detection needs a probe card equipped with a probe module having probes provided with tiny pinpoints and high positional accuracy. But the commercially available probes are difficult to meet such demand. Although the microelectromechanical manufacturing process can provide probes with high positional accuracy, the steps of photolithography and electroforming must be repeated many times to manufacture the probe with gradually narrowing probe tip by the microelectromechanical manufacturing process. That is time-consuming, low in yield rate, and still difficult to form the probe with tiny pinpoint. Therefore, the probe modules of the commercially available probe cards are difficult to be applied to the detection of tiny electronic components such as micro LED (light-emitting diode).

For example, a conductive pad of a micro LED has an area with an approximate diameter of only 4 micrometers (μm) for the probe to contact. In the application to the probe cards, the conventional vertical probes, including the traditional probes such as Cobra-shaped probes and the microelectromechanical probes, should be inserted through dies with guiding holes, the general positional accuracy of which is about ±12.5 μm. The general positional accuracy of the conventional traditional cantilever probes is about ±5 μm. The general positional accuracy of the conventional microelectromechanical cantilever probes is about ±3 μm. Each of the aforementioned positional accuracy has a range larger than the area of the conductive pad of the micro LED for the probe to contact, so the conventional probe modules equipped with the aforementioned probes are all inapplicable to the detection of the micro LED.

### SUMMARY OF THE INVENTION

The present invention has been accomplished in view of the above-noted circumstances. It is a primary objective of the present invention to provide a probe module having a microelectromechanical probe and a method of manufacturing the probe module, wherein the microelectromechanical probe has a probe tip provided with a tiny pinpoint so as to be applicable to the detection of tiny electronic components, and the method of manufacturing the probe module is time-saving and high in yield rate.

To attain the above objective, the present invention provides a probe module which includes a circuit board and at least one microelectromechanical probe formed on a probe installation surface of the circuit board by a microelectromechanical manufacturing process. The microelectromechanical probe includes a probe body and a probe tip. The probe body includes a first end portion, a second end portion and a longitudinal portion extending from the first end portion to the second end portion along a longitudinal axis. The longitudinal portion has a first surface facing toward a first direction substantially perpendicular to the longitudinal axis and a second surface facing toward a second direction opposite to the first direction. The probe tip extends from the probe body toward the first direction and is processed with a gradually narrowing shape by laser cutting so as to have a pinpoint. At least one of the first end portion and the second end portion has a supporting seat protruding from the second surface toward the second direction. The supporting seat is connected to the probe installation surface of the circuit board in a way that the longitudinal portion and the probe tip are suspended above the probe installation surface.

In the condition that only the first end portion has the supporting seat, the microelectromechanical probe is approximately N-shaped, the second end portion of the probe body is suspended above the probe installation surface, and the probe tip extends from the second end portion toward the first direction. In the condition that the first end portion and the second end portion both have the supporting seat, two end portions of the probe are both fixed onto the circuit board, so that the longitudinal portion and the probe tip, which are located between the two end portions, are suspended in a way that the probe is configured as being a bridge structure. No matter in which of the above-described conditions, the probe tip, which is formed by laser cutting, may have a tiny pinpoint. Microscopically, the pinpoint of the probe tip has an arc surface, and the width of the arc surface may be smaller than 5 micrometers. Therefore, the probe module of the present invention, which has the microelectromechanical probe, is applicable to the detection of tiny electronic components.

To attain the above objective, the present invention further provides a method of manufacturing the above-described probe module having the microelectromechanical probe, which includes the steps of:
a) forming at least one needle on the probe installation surface of the circuit board by the microelectromechanical manufacturing process in a way that the needle includes the probe body and a processing reserved portion extending from the probe body toward the first direction;
b) defining a pinpoint position on the processing reserved portion; and
c) processing the processing reserved portion into the probe tip by laser cutting in a way that the pinpoint of the probe tip is located at the pinpoint position.

As a result, the above-described microelectromechanical probe having the probe tip with tiny pinpoint can be manufactured by the above-mentioned method, and the method is relatively more time-saving and higher in yield rate. In particularly, by the method, a plurality of the above-described microelectromechanical probes can be manufactured in a same process, and the probe tips of the microelectromechanical probes can be processed in an absolute coordinate manner, so that the probe tips are relatively higher in positional accuracy, thereby more applicable to the detection of tiny electronic components.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic perspective view of a probe module having microelectromechanical probes according to a first preferred embodiment of the present invention.

FIGS. 2-7 are schematic sectional views showing steps of a manufacturing process of the probe module according to the first preferred embodiment of the present invention.

FIGS. 8 and 9 are partially schematic perspective views of a microelectromechanical probe of the probe module according to the first preferred embodiment of the present invention before and after a laser cutting process, respectively.

FIG. 10 is a partially schematic view of the microelectromechanical probe.

FIGS. 11 and 12 are partially schematic perspective views of another type of the microelectromechanical probe before and after the laser cutting process, respectively.

FIGS. 13 (a) to (h) are partially schematic views of eight other types of the microelectromechanical probe, respectively.

FIGS. 14 and 15 are partially schematic views of still another type of the microelectromechanical probe before and after the laser cutting process, respectively.

FIG. 16 is a schematically top view of some microelectromechanical probes of the probe module shown in FIG. 1 before the laser cutting process.

FIGS. 17 and 18 are respectively a partially schematic perspective view and a partially schematic top view of three microelectromechanical probes of a probe module according to a second preferred embodiment of the present invention.

FIG. 19 is a schematic perspective view of two microelectromechanical probes of a probe module according to a third preferred embodiment of the present invention.

FIG. 20 is a partially enlarged view of FIG. 19.

FIG. 21 is a schematic perspective view of three microelectromechanical probes of a probe module according to a fourth preferred embodiment of the present invention.

FIG. 22 is a partially enlarged view of FIG. 21.

FIG. 23 is a schematic perspective view of four microelectromechanical probes of a probe module according to a fifth preferred embodiment of the present invention.

FIG. 24 is a partially enlarged view of FIG. 23.

FIG. 25 is a schematic perspective view of a probe module having microelectromechanical probes according to a sixth preferred embodiment of the present invention.

FIG. 26 is a partially schematic perspective view of a microelectromechanical probe of the probe module according to the sixth preferred embodiment of the present invention.

FIG. 27 is a schematically enlarged view of FIG. 16, but showing the condition that the pinpoint positions of some needles are deviated from the central points of their processing reserved portions.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice.

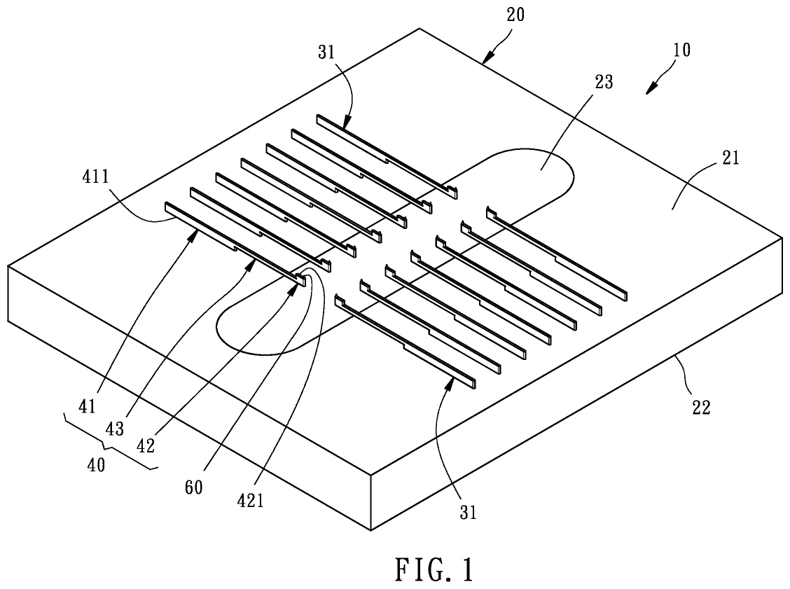

Referring to FIG. 1, a probe module 10 according to a first preferred embodiment of the present invention includes a circuit board 20 and fourteen microelectromechanical probes 31 disposed on the circuit board 20. It is to be mentioned that in this specification, the microelectromechanical probe is also called “the probe” for concise illustration. The probe module of the present invention may include at least one probe, which means the amount of the probe is unlimited. The method of manufacturing the probe module 10 will be described below, and the structural features of the probe module 10 will be also described. The method of manufacturing the probe module 10 includes the following steps.

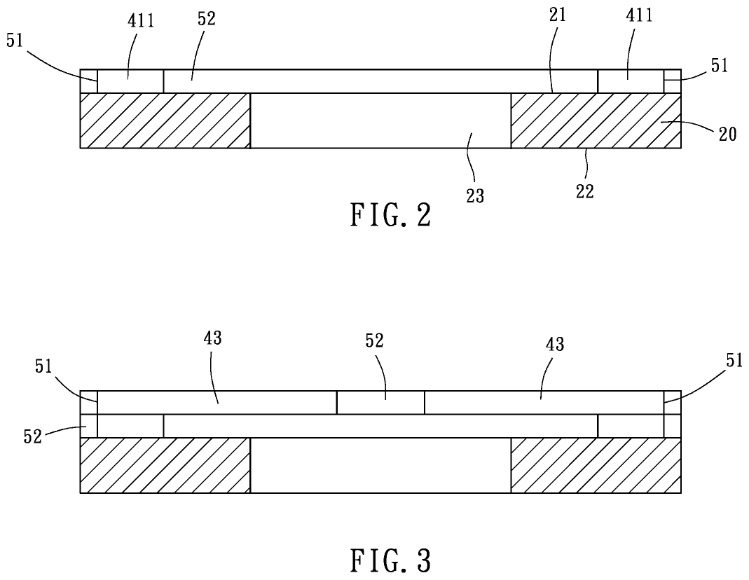

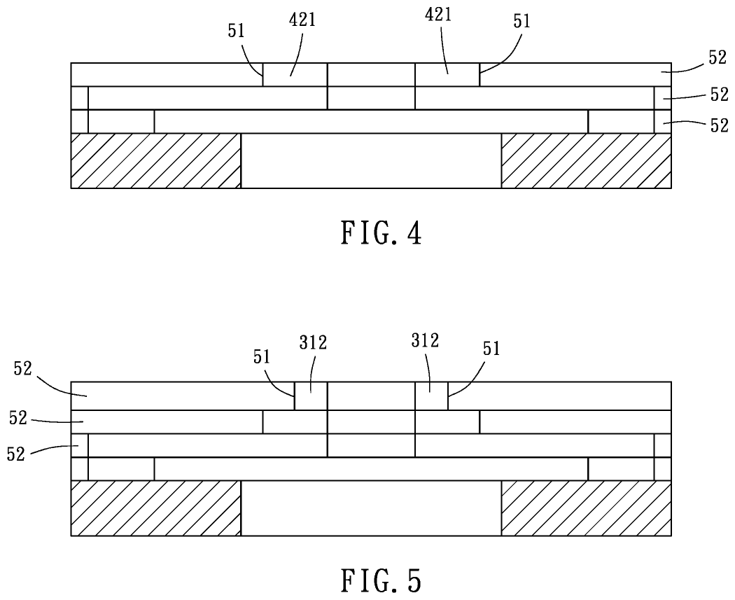

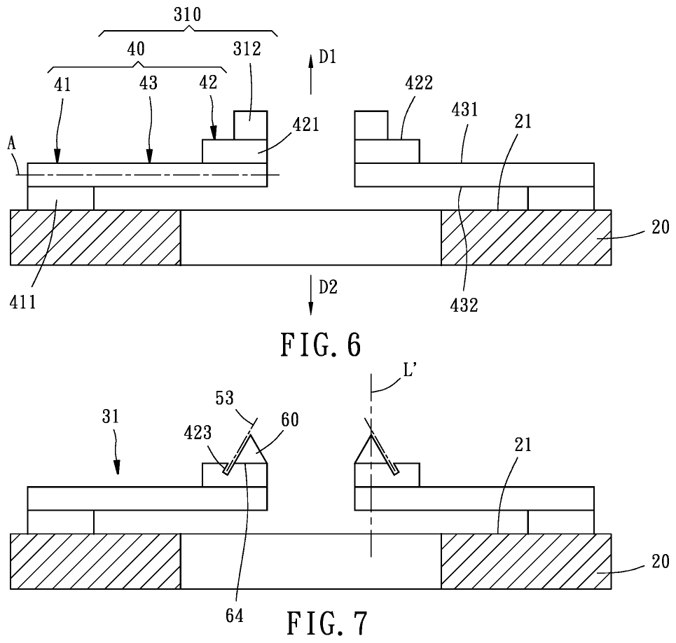

As shown in FIGS. 2-6, the step a) is forming at least one needle 310 on a probe installation surface 21 of the circuit board 20 by a microelectromechanical manufacturing process. The needle 310 is schematically shown in FIG. 6, the amount of which is equal to the amount of the microelectromechanical probe 31. The needle 310 includes a probe body 40 and a processing reserved portion 312 extending from the probe body 40 toward a first direction Dl.

It should be noticed that the circuit board 20, the needles 310 and the probes 31 shown in FIGS. 2-7 are not drawn correspondingly in shape to the probe 31 shown in FIG. 1. The shape shown in FIG. 1 is relatively nearer the actual shape. In FIGS. 2-7, however, the scale is changed in a way that the length of the needle is shortened and the structural features are enlarged, for the simplification of the figures. Besides, the microelectromechanical probes 31 are made by a same manufacturing method, and the needles 310 thereof can be formed in a same microelectromechanical manufacturing process. In the following description, the manufacturing process will be specified under the condition of manufacturing a single microelectromechanical probe 31.

In this embodiment, the circuit board 20 has an elongated through hole 23 penetrating through the probe installation surface 21 and a connecting surface 22, for the probe 31 to partially enter the through hole 23 when the probe 31 is bended and deformed by a force. The through hole 23 may be formed before the manufacturing process or after the manufacturing process by processing. In fact, the probe installation surface 21 and the connecting surface 22 of the circuit board 20 are both provided with many electrical contact pads, which are not shown in the figures for the simplification of the figures. Besides, the circuit board 20 is provided therein with many circuits connecting the electrical contact pads of the probe installation surface 21 and the electrical contact pads of the connecting surface 22, which are not shown in the figures for the simplification of the figures. The electrical contact pads are very thin and almost not prominent, so the probe installation surface 21 and the connecting surface 22 are substantially flat. The electrical contact pads of the probe installation surface 21 are adapted for directly electrical connection with the microelectromechanical probes 31. The electrical contact pads of the connecting surface 22 are adapted for directly electrical connection with a main circuit board (not shown) of a probe card or a space transformer (not shown) disposed between the main circuit board and the circuit board 20, so that the probes 31 are electrically connected with the main circuit board indirectly. The circuit board 20 may be the conventional multi-layer ceramic board (also called MLC for short), multi-layer organic board (also called MLO for short) or printed circuit board (also called PCB for short).

In the drawings of the present invention, the probe installation surface 21 faces upward and the connecting surface 22 faces downward. Such directionality corresponds to the state in the manufacturing process, not the usage state. In general, the probe installation surface 21 for the probe 31 to be formed thereon faces downward in the usage state, so that the probe 31 can be moved downward to contact the device under test (not shown). In the manufacturing process, the probe installation surface 21 faces upward for the convenience of forming the probe 31 on the probe installation surface 21.

The microelectromechanical manufacturing process in the step a) refers to forming sacrificial layers 52 layer by layer on the probe installation surface 21 of the circuit board 20 by photolithography in a way that each sacrificial layer 52 is made of easily removable metal or photoresist and provided at a specific position with an opening 51, and then forming each part of the metallic (e.g. nickel-cobalt alloy) microelectromechanical probe 31 in the opening 51 of each sacrificial layer 52 by electroplating. For example, in the microelectromechanical manufacturing process in the step a) in this embodiment, four sacrificial layers 52 are formed and the electroplating process is performed for four times after the sacrificial layers 52 are formed respectively, so that a part of the probe 31 is formed in each time of the electroplating process, as shown in FIGS. 2-5. After that, the sacrificial layers 52 are removed, and the required needle 310 is left on the probe installation surface 21 of the circuit board 20, as shown in FIG. 6. Such microelectromechanical manufacturing process belongs to the prior art and has been disclosed in many prior arts, including but not limited to Taiwan Patent No. 1413775, so the details of the microelectromechanical manufacturing process will not be repeatedly described hereinafter.

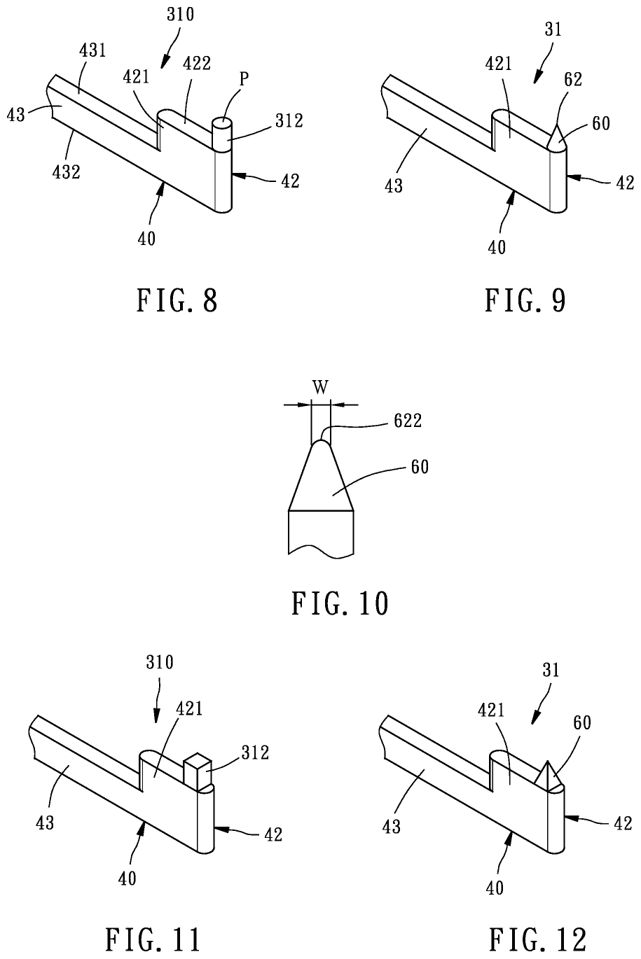

As shown in FIG. 6, the needle 310 is divided into the probe body 40 and the processing reserved portion 312, wherein the probe body 40 needs no additional processing before serving as the probe body of the microelectromechanical probe 31, but the processing reserved portion 312 will be processed in the following steps. In this embodiment, the needle 310 is shaped as the conventional microelectromechanical cantilever probe, which is also called N-shaped probe. The probe body 40 includes a first end portion 41, a second end portion 42 and a longitudinal portion 43 extending from the first end portion 41 to the second end portion 42 along a longitudinal axis A. The first end portion 41 has a supporting seat 411 directly connected to the probe installation surface 21 of the circuit board 20, which is formed in the first time of the electroplating process as shown in FIG. 2. Specifically speaking, the supporting seat 411 is electrically and mechanically connected to an electrical contact pad of the probe installation surface 21, and the other parts of the needle 310 are piled upwardly from the supporting seat 411 to be suspended above the probe installation surface 21. The longitudinal portion 43 has a first surface 431 facing toward the first direction D1 substantially perpendicular to the longitudinal axis A, and a second surface 432 facing toward a second direction D2 opposite to the first direction D1. The supporting seat 411 protrudes from the second surface 432 toward the second direction D2. The second end portion 42 has a probe tip seat 421 protruding from the first surface 431 toward the first direction D1. The processing reserved portion 312 extends from a part of a top surface 422 of the probe tip seat 421 toward the first direction D1. The probe tip seat 421 and the processing reserved portion 312 have shapes shown in FIG. 8, wherein the probe tip seat 421 is shaped as a relatively wider cylinder having the relatively larger top surface 422, and the processing reserved portion 312 extends from a circular area located at an end of the top surface 422 to be shaped as a circular cylinder.

The step b) is defining a pinpoint position P on the processing reserved portion 312. As shown in FIG. 8, the pinpoint position P may, but unlimited to, be defined at the central point of the top surface of the processing reserved portion 312.

As shown in FIG. 7, the step c) is processing the processing reserved portion 312 into a probe tip 60 by laser cutting in a way that the probe tip 60 is processed with a gradually narrowing shape so as to have a pinpoint 62 located at the pinpoint position P, as shown in FIG. 9.

As shown in FIG. 7, the laser beam 53 for performing the laser cutting process inclinedly cuts into the processing reserved portion 312 according to the desired pinpoint position P. In this embodiment, the laser beam 53 cuts into the processing reserved portion 312 and makes a circle to produce the cone-shaped probe tip 60 as shown in FIG. 9. It should be mentioned that in the ideal condition, the laser beam 53 cuts into the processing reserved portion 312 only. However, due to the inclined angle and energy of the laser beam 53, the laser beam 53 has an eighty percent probability of cutting into the probe tip seat 421 to produce a slot 423 adjacent to the probe tip 60, as shown in FIG. 7. More specifically, the slot 423 is formed around a contour of a bottom surface 64 of the probe tip 60. Because the needle 310 has the probe tip seat 421, the longitudinal portion 43 is prevented from being cut by the laser beam 53, thereby prevented from fracture due to the slot produced by the laser beam 53 when being bended and deformed.

It can be known from the above description that for the microelectromechanical probe 31 of the present invention, a part of the needle 310 formed by the microelectromechanical manufacturing process, i.e. the processing reserved portion 312, is further processed by laser cutting to be formed into the probe tip 60, and the pinpoint 62 is provided at a predetermined position, i.e. the pinpoint position P, by this laser cutting process. The pinpoint 62 produced in such manner is tiny. Specifically speaking, the pinpoint 62 of the probe tip 60 has an arc surface 622 which is enlargedly shown in FIG. 10 for the convenience of illustration, and the width w of the arc surface 622 is smaller than 5 micrometers. As a result, the pinpoint 62 of the probe tip 60 is adapted to contact the tiny conductive pad of the device under test, so the probe module 10 and the microelectromechanical probe 31 of the present invention are applicable to the detection of tiny electronic components.

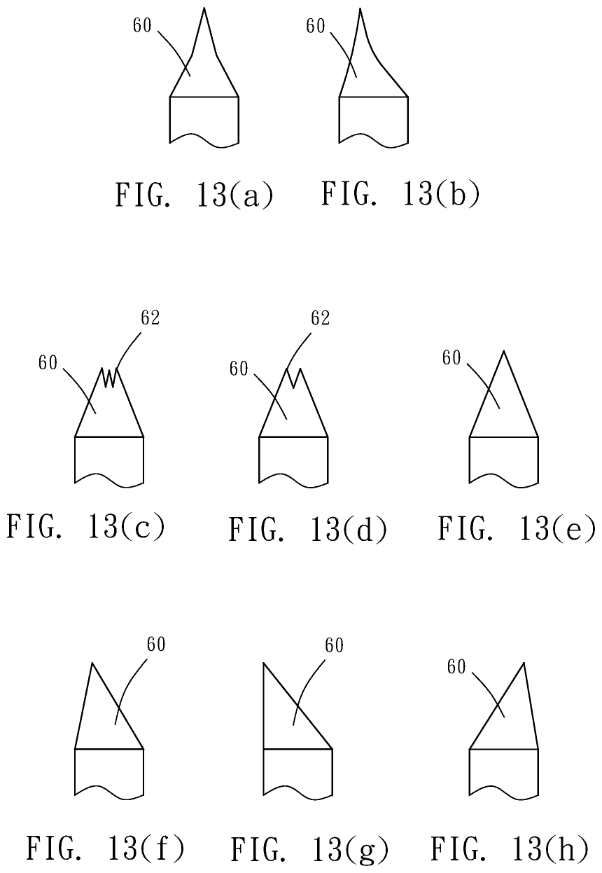

As shown in FIGS. 11 and 12, the processing reserved portion 312 formed in the aforementioned step a) may be shaped as a polygonal cylinder such as the quadrangular cylinder as shown in FIG. 11, and the probe tip 60 formed from the processing reserved portion 312 by laser cutting in the step c) may be shaped as a polygonal pyramid such as the quadrangular pyramid as shown in FIG. 12. In fact, for the microelectromechanical probe of the present invention, the shape of the probe tip 60 is unlimited, as long as it is a gradually narrowing shape so that the probe tip 60 has the tiny pinpoint 62. For example, the probe tip 60 may be shaped as shown in FIGS. 13 (a) to (h). As shown in FIGS. 13 (a) and (b), the probe tip 60 may be gradually narrowed in a multi-gradation manner. As shown in FIGS. 13 (c) and (d), the probe tip 60 may have a plurality of pinpoints 62. As shown in FIGS. 13 (e) to (h), the probe tip 60 may be shaped with symmetry or asymmetry.

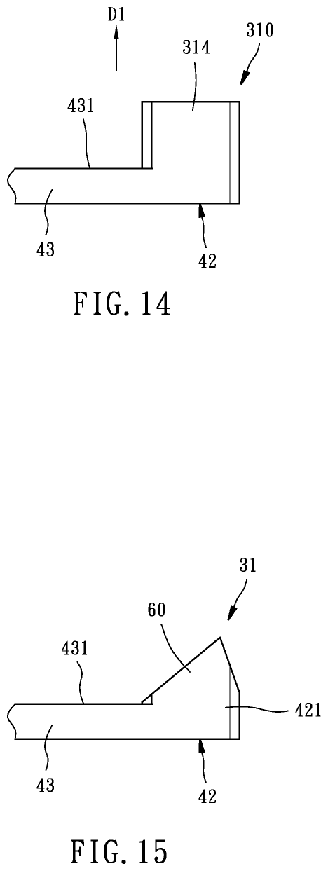

The shape of the processing reserved portion 312 is unlimited, as long as it can be processed into the desired shape of the probe tip. The processing reserved portion 312 may be shaped as a circular cylinder, an elliptic cylinder, a polygonal cylinder, and so on. Besides, the processing reserved portion 312 is unlimited to be prominent on the top surface 422 of the probe tip seat 421, but may extend from the probe tip seat 421 in a way that the processing reserved portion 312 and the probe tip seat 421 are continuous in shape, as shown in FIG. 14. Specifically speaking, the needle 310 before the laser cutting process has a column 314 protruding from the first surface 431 of the longitudinal portion 43 toward the first direction D1 continuously in shape, and the column 314 includes the probe tip seat 421 and the processing reserved portion 312. As shown in FIG. 15, a part of the column 314, i.e. the processing reserved portion 312, is processed into the gradually narrowing probe tip 60 by laser cutting, and the non-cut part at the bottom of the column 314 is considered as the probe tip seat 421. The whole column 314 may only serve as the processing reserved portion 312, which means there may be no non-cut part left at the bottom of the column 314 after the laser cutting process. In other words, the needle 310 may have no such probe tip seat 421, so that the processing reserved portion 312 is directly connected to the first surface 431, and after the laser cutting process the probe tip 60 is directly connected to the first surface 431.

The above description is primarily related to the manufacturing process and the structural features of a single microelectromechanical probe 31. In the condition that the probe module 10 has a plurality of microelectromechanical probes 31, the probes 31 are usually formed on the circuit board 20 in a way that the longitudinal axes A of at least some of the probes 31 are parallel to each other and the probe tips 60 thereof are aligned in a line. For example, in the probe module 10 shown in FIG. 1, seven probes 31 are aligned in a line, and seven other probes 31 are aligned in another line. The needles 310 of the probes 31 can be formed at the same time in the aforementioned step a) and then processed by laser cutting in an absolute coordinate positioning manner.

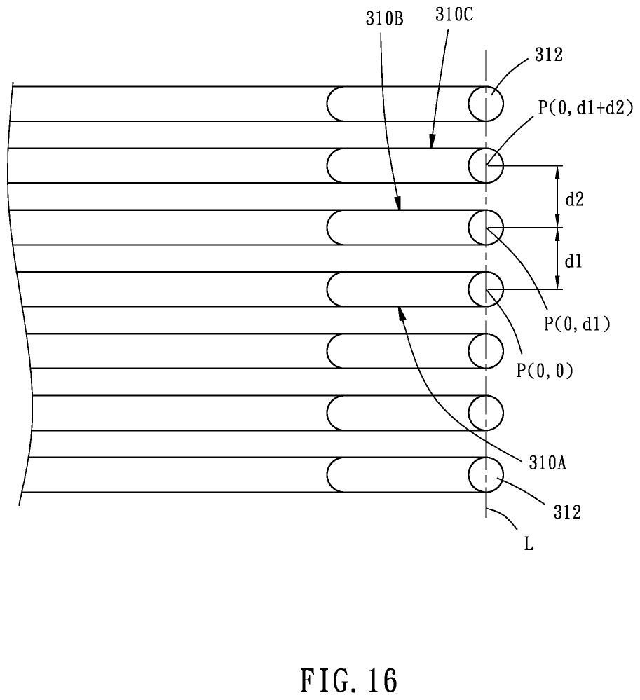

Specifically speaking, FIG. 16 shows the needles 310 corresponding to one of the two rows of probes 31 as shown in FIG. 1 before being processed by laser cutting, including the needles 310A-C. In the step b), an imaginary straight line L is firstly defined in a way that the processing reserved portions 312 of the needles 310 are aligned along the imaginary straight line L. Then, one of the needles 310 is chosen to serve as a reference needle 310A, and a reference origin, i.e. the coordinate (0,0), is defined on the processing reserved portion 312 of the reference needle 310A and the imaginary straight line L. The reference origin is defined as the pinpoint position P of the reference needle 310A. Then, the pinpoint position P of each remainder needle 310 is defined on the imaginary straight line L in an absolute coordinate manner according to the reference origin, which means the pinpoint position P of each remainder needle 310 is set according to the predetermined intervals between the pinpoints 62 of the probes 31. For example, the predetermined interval between the pinpoints of the probes corresponding to the needle 310B and the needle 310A is d1, then the pinpoint position P of the needle 310B is defined at the coordinate (0,d1). In addition, the predetermined interval between the pinpoints of the probes corresponding to the needle 310C and the needle 310B is d2, then the pinpoint position P of the needle 310C is defined at the coordinate (0,d1+d2). The pinpoint positions P of the other needles are defined in a similar fashion. After that, in the step c), the processing reserved portions 312 of the needles 310 are processed into the probe tips 60 of the needles 310 by laser cutting in a way that the pinpoints 62 of the probe tips 60 are located at the pinpoint positions P respectively.

The general positional accuracy of the needles 310 formed by the microelectromechanical manufacturing process in the step a) is about ±3 μm, and the accuracy of the laser cutting process performed in the absolute coordinate manner in the steps b) and c) is generally ±1.5 μm. Therefore, the positional error of the needles 310 formed in the step a) can be corrected by the steps b) and c) to cause the pinpoints 62 of the probe tips 60 to be substantially located at the predetermined positions, so that the probe module 10 is more applicable to the detection of tiny electronic components. In the condition of a small number of probes 31, anyone of the needles 310 can be chosen to serve as the reference needle 310A. However, in the condition of a large number of probes 31, for preventing some of the needles 310 from too large positional error to be defined on the processing reserved portions 312 thereof with the pinpoint positions P in the absolute coordinate manner, it is preferable to choose the needle near the middle position as the reference needle 310A. More preferably, in the step b), the needles 310 can be defined according to aligned order thereof, such as the order from the top to the bottom in FIG. 16, with ordinal numbers from 1 to n. In the condition that n is an odd number, the reference needle 310A is the needle with the ordinal number n+1/2. In the condition that n is an even number, the reference needle is the needle with the ordinal number n/2 or the needle with the ordinal number n/2+1. In other words, the middle needle 310 serves as the reference needle 310A. For example, in this embodiment n=7, and the reference needle 310A is the fourth needle, i.e. the needle with the ordinal number 4.

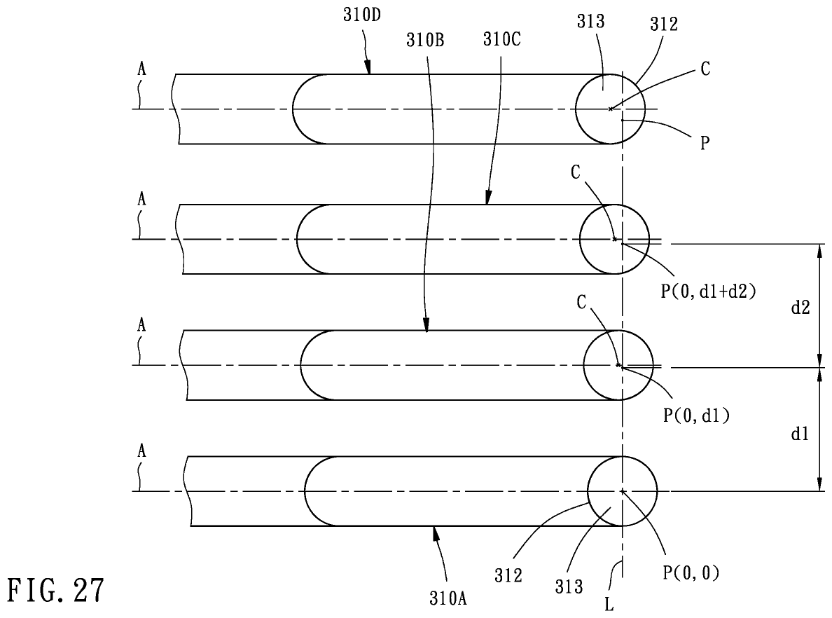

In other words, the pinpoint position P(0,0) of the reference needle 310A can be directly defined at the central point of the top surface 313 of the processing reserved portions 312 thereof. However, the pinpoint positions P of the other needles are defined in the absolute coordinate manner, thereby possibly located at the positions other than the central points C of the top surfaces 313 of the processing reserved portions 312 thereof and possibly deviated from the longitudinal axes A thereof. That means, in the microscopic view as shown in FIG. 27, the pinpoint positions P of the partial needles are deviated from the central points C of the top surfaces 313 of the processing reserved portions 312 thereof. Besides, the farther the needle is distanced from the reference needle 310A, the farther the pinpoint position P thereof is deviated from the central point C of the top surface 313 of the processing reserved portion 312 thereof. For example, in FIG. 27, the deviation of the pinpoint position P of the needle 310C is more obvious than the deviation of the pinpoint position P of the needle 310B, the deviation of the pinpoint position P of the needle 310D is more obvious than the deviation of the pinpoint position P of the needle 310C, and so on. Further speaking, the probe tip 60 of the probe has a bottom surface 64 as shown in FIG. 7, i.e. the surface connected with the probe body 40 and facing toward the second direction D2. In this embodiment, the bottom surface 64 is connected with the top surface 422 of the probe tip seat 421. The bottom surface 64 is also the surface of the processing reserved portion 312, which is provided opposite to the top surface 313. The bottom surface 64 of the probe tip 60 is located opposite to the pinpoint 62 of the probe tip 60. As the above description, defining the pinpoint position P in the absolute coordinate manner causes deviation to the pinpoint positions P of the partial needles. Therefore, after the probe tips 60 of the probes are processed, for one of the probes, the projection of the pinpoint 62 of the probe tip 60 is located at the center of the bottom surface 64 of the probe tip 60, which means the pinpoint 62 and the center of the bottom surface 64 are located on the same imaginary straight line L′ perpendicular to the longitudinal axis A as shown in FIG. 7. For example, the pinpoint position P(0,0) of the reference needle 310A is located at the projection of the center of the bottom surface 64, i.e. the central point C of the top surface 313 of the processing reserved portion 312 of the reference needle 310A. For at least another of the probes, the projection of the pinpoint 62 of the probe tip 60 is deviated from the center of the bottom surface 64 of the probe tip 60. For example, the pinpoint positions P of the needles 310B-D are deviated from the projections of the centers of the associated bottom surfaces 64, i.e. the central points C of the top surfaces 313 of the processing reserved portions 312 of the needles 310B-D.

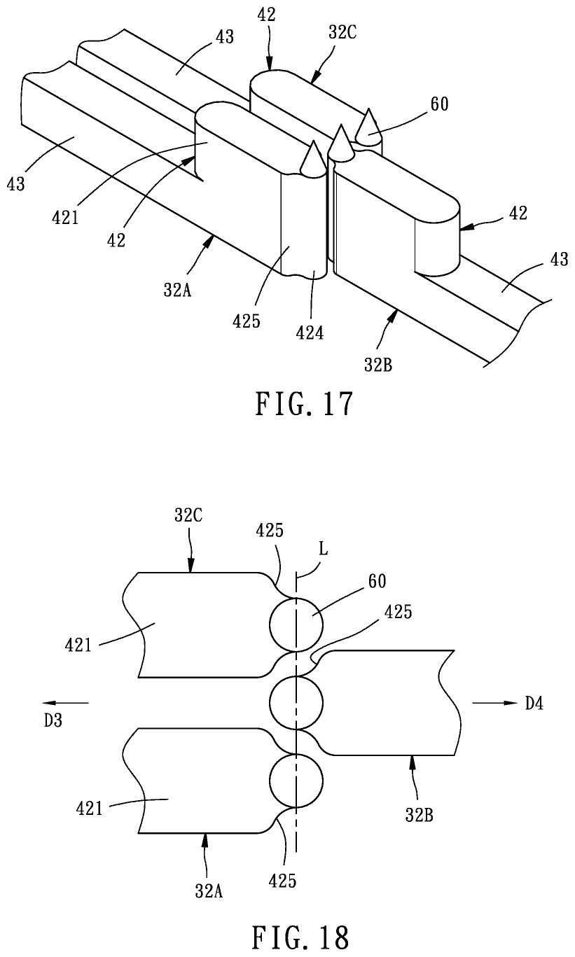

FIGS. 17 and 18 show three of the microelectromechanical probes of a probe module according to a second preferred embodiment of the present invention, which illustrates that the probe tips 60 of the two rows of microelectromechanical probes of the probe module are unlimited to be aligned in two lines as shown in FIG. 1, but may be aligned along the same imaginary straight line L. In other words, every two microelectromechanical probes in the second preferred embodiment, whose probe tips 60 are aligned along the imaginary straight line L and located adjacent to each other, extend toward two sides of the imaginary straight line L respectively. For example, the longitudinal portion 43 of the first probe 32A extends from the second end portion 42 toward a third direction D3 substantially perpendicular to the imaginary straight line L, and the longitudinal portion 43 of the second probe 32B located adjacent to the probe tip of the first probe 32A extends from the second end portion 42 toward a fourth direction D4 opposite to the third direction D3. The third probe 32C located adjacent to the probe tip of the second probe 32B has an extending direction same as that of the first probe 32A, i.e. the longitudinal portion 43 of the third probe 32C extends from the second end portion 42 toward the third direction D3. The other probes (not shown) extend in a similar fashion.

In the above-described condition that the probes whose probe tips are located adjacent to each other extend toward opposite directions, the probes may be shaped in a way as shown in FIGS. 17 and 18 that the terminal of the second end portion 42 is relatively narrower and the other parts are relatively wider. Specifically speaking, the second end portion 42 of each of the probes 32A-C has a connecting section 424 directly connected with the probe tip 60 and two concaves 425 located by two sides of the connecting section 424 respectively. Apart of the connecting section 424 of the first probe 32A and a part of the connecting section 424 of the third probe 32C are located in the two concaves 425 of the second probe 32B respectively. The connecting section 424 of the second probe 32B is also partially located in one of the concaves 425 of the first probe 32A and one of the concaves 425 of the third probe 32C.

As a result, except for the terminal of the second end portion 42, the other parts of the probes 32A-C can be provided with relatively larger width to have relatively higher structural strength, which can still fulfill the requirement of relatively smaller interval between the probe tips 60 because the concaves 425 of the second end portions 42 enables the probe tips 60 to be located relatively closer to each other. Such effect can be also attained by the structures described in the following third to fifth preferred embodiments.

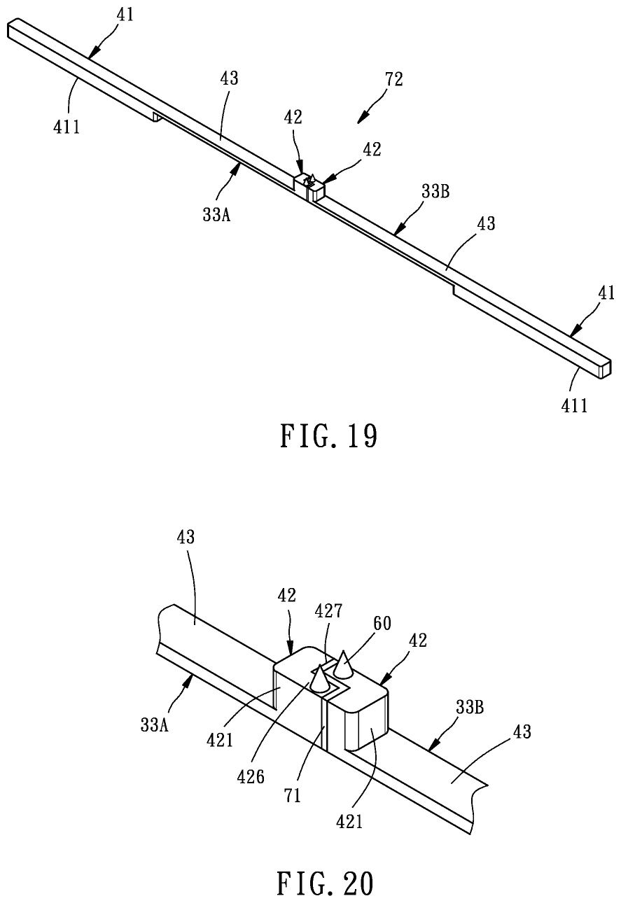

FIGS. 19 and 20 show two of the microelectromechanical probes of a probe module according to a third preferred embodiment of the present invention, wherein the first probe 33A and the second probe 33B are similar to the first probe 32A and the second probe 32B of the second preferred embodiment, but the second and third preferred embodiments are different in the shape of the second end portions 42 of the probes. Besides, in the third preferred embodiment, the second end portion 42 of the first probe 33A and the second end portion 42 of the second probe 33B are combined together and insulated from each other by an insulating layer 71, so that the first and second probes 33A and 33B are combined into a double-probe type of probe set unit 72. Specifically speaking, the probes 33A and 33B are shaped identically, each of which is provided on the second end portion 42 thereof with a protrusion 426 substantially protruding along the longitudinal axis A and a recess 427 located adjacent to the protrusion 426. The probe tips 60 of the probes 33A and 33B are located on the protrusions 426 respectively. The protrusion 426 of the first probe 33A is disposed in the recess 427 of the second probe 33B and insulated from the second probe 33B by the insulating layer 71. The protrusion 426 of the second probe 33B is disposed in the recess 427 of the first probe 33A and insulated from the first probe 33A by the insulating layer 71. In other words, the second end portions 42 of the two probes 33A and 33B are approximately complementary in shape and combined into a complete shape through the insulating layer 71. Such probes 33A and 33B can be manufactured with relatively larger width to have relatively higher structural strength, and also fulfill the requirement of relatively smaller intervals between the probe tips 60 by the structure of the second end portions 42.

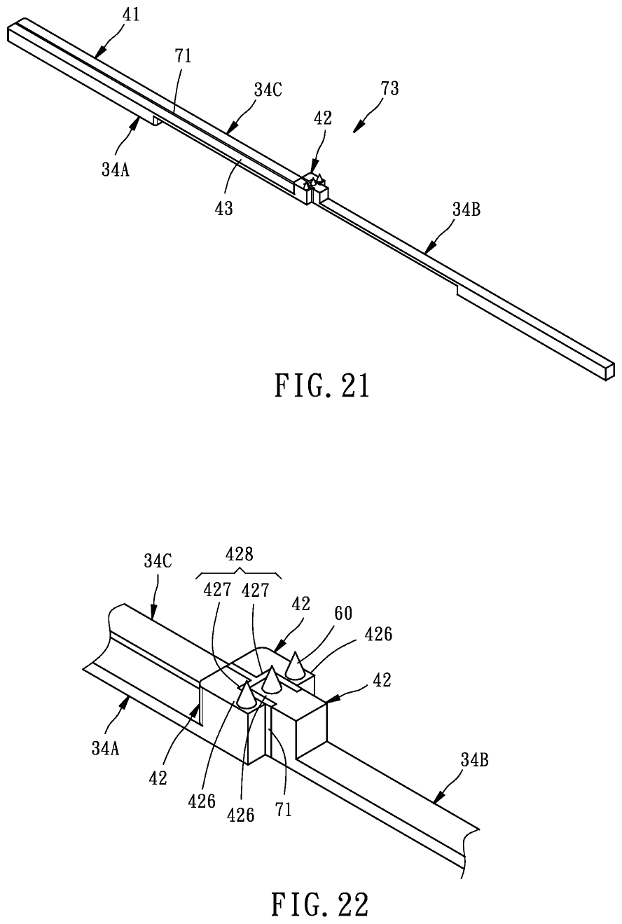

FIGS. 21 and 22 show three of the microelectromechanical probes of a probe module according to a fourth preferred embodiment of the present invention, wherein the first to third probes 34A-C are similar to the first to third probes 32A-C of the second preferred embodiment, but the second and fourth preferred embodiments are different in the shape of the second end portions 42 of the probes. Besides, in the fourth preferred embodiment, the second end portions 42 of the probes 34A-C are combined together and insulated from each other by an insulating layer 71, so that the probes 34A-C are combined into a triple-probe type of probe set unit 73. In addition, the first end portion 41 and the longitudinal portion 43 of the third probe 34C are combined with the first end portion 41 and the longitudinal portion 43 of the first probe 34A respectively and insulated from the first probe 34A by the insulating layer 71. Specifically speaking, the first and third probes 34A and 34C are shaped symmetrically to each other, each of which is provided on the second end portion 42 thereof with a protrusion 426 substantially protruding along the longitudinal axis A and a recess 427 located adjacent to the protrusion 426. The second probe 34B has a protrusion 426 substantially protruding along the longitudinal axis A. The probe tips 60 of the probes 34A-C are located on the protrusions 426 respectively. The recesses 427 of the first and third probes 34A and 34C collectively form a concave 428. The protrusion 426 of the second probe 34B is disposed in the concave 428 and insulated from the first and third probes 34A and 34C by the insulating layer 71. Such probes 34A-C can be manufactured with relatively larger width to have relatively higher structural strength, and also fulfill the requirement of relatively smaller intervals between the probe tips 60 by the structure of the second end portions 42. Besides, the first and second end portions 41 and 42 and the longitudinal portion 43 of the first probe 34A are combined with the first and second end portions 41 and 42 and the longitudinal portion 43 of the third probe 34C, so the structural strength is further increased.

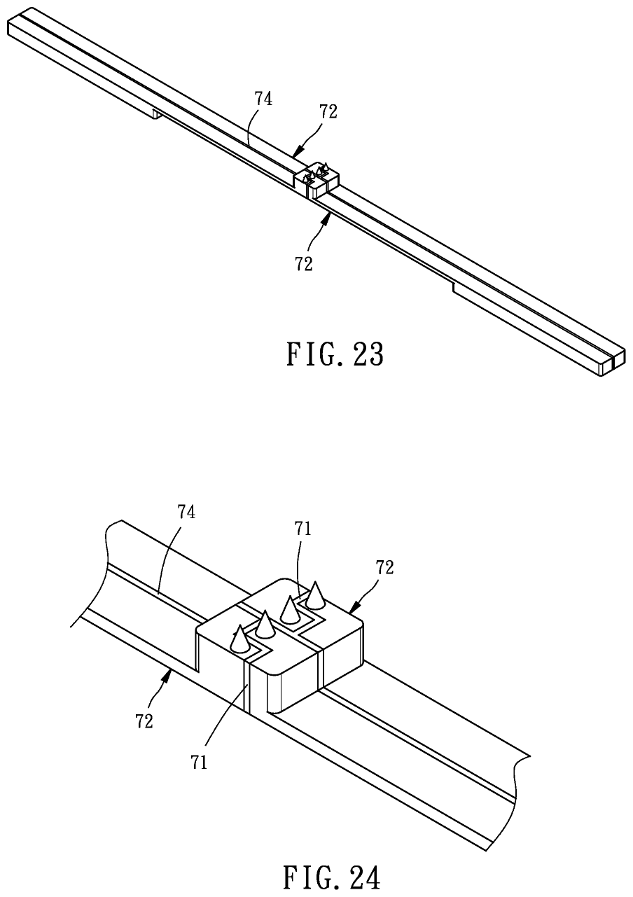

FIGS. 23 and 24 show four of the microelectromechanical probes of a probe module according to a fifth preferred embodiment of the present invention, the structure of which includes two aforementioned double-probe type of probe set units 72 which are combined together and insulated from each other by another insulating layer 74. It is obvious that two aforementioned triple-probe type of probe set units 73 can be combined together and insulated from each other by another insulating layer. Besides, in such manner, there may be more probe set units 72 or 73 combined together.

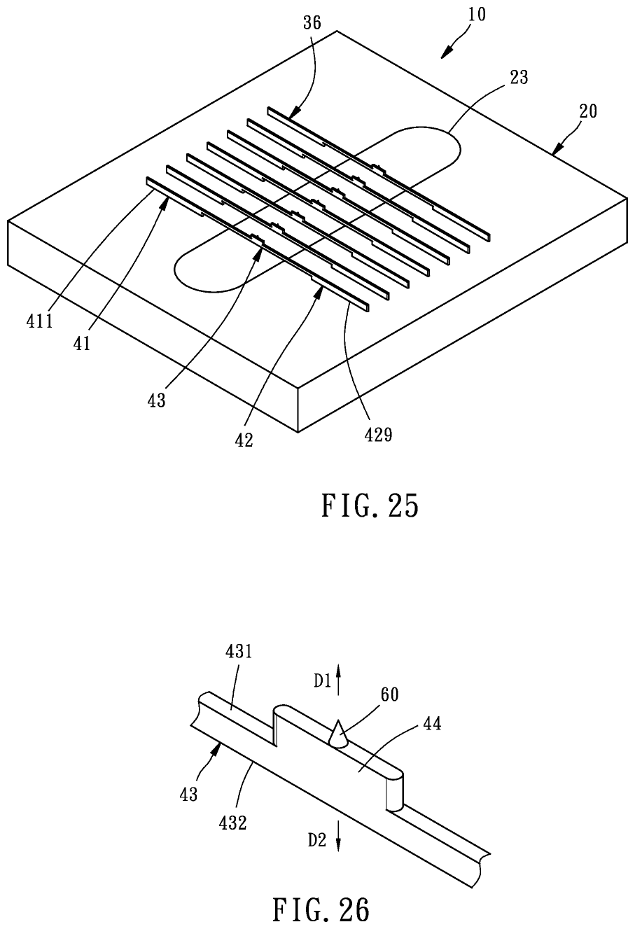

The microelectromechanical probes in the above embodiments are all cantilever probes or also called N-shaped probes, the longitudinal portions 43, the second end portions 42 and the probe tips 60 of which are all suspended above the probe installation surface 21 of the circuit board 20. In the third to fifth preferred embodiments, the second end portions 42 of a plurality of probes are combined together, so that the plurality of probes form a bridge configuration. In the present invention, a single probe can be also manufactured into the above-described bridge configuration, such as each microelectromechanical probe 36 of a probe module 10 according to a sixth preferred embodiment of the present invention as shown in FIGS. 25 and 26. The first and second end portions 41 and 42 of the microelectromechanical probe 36 both have the supporting seats 411 and 429 connected to the probe installation surface 21 of the circuit board 20, which means the first and second end portions 41 and 42 may be shaped identically. The probe tip seat 44 and the probe tip 60 of the microelectromechanical probe 36 are located between the first and second end portions 41 and 42. The probe tip seat 44 extends from the first surface 431 of the longitudinal portion 43 toward the first direction D1. The probe tip 60 extends from the probe tip seat 44 toward the first direction D1.

No matter in the bridge configuration formed by a single probe in the sixth preferred embodiment or the bridge configuration formed by a plurality of probes in the third to fifth preferred embodiments, when the probe tip 60 of the microelectromechanical probe contacts the conductive pad of the device under test and thereby moves into the through hole 23 of the circuit board 20 to cause the longitudinal portion 43 to bend toward the second direction D2, the probe tip 60 in the third to sixth preferred embodiments doesn't move along an arc path like that in the first and second preferred embodiments, but substantially moves along a straight path toward the second direction D2 because of the aforementioned bridge configuration. In other words, when the probe tip 60 moves, the position thereof changes vertically only, but doesn't change horizontally. As a result, the positional accuracy of the probe tip 60 contacting the device under test is relatively higher, therefore such probe module is more applicable to the detection of tiny electronic components.

The invention being thus described, it will be obvious that the same may be varied in many ways. Such variations are not to be regarded as a departure from the scope of the invention, and all such modifications as would be obvious to one skilled in the art are intended to be included within the scope of the following claims.

What is claimed is:

1. A probe module comprising:
a circuit board having a probe installation surface; and
at least one microelectromechanical probe formed on the probe installation surface of the circuit board by a microelectromechanical manufacturing process, the microelectromechanical probe comprising a probe body and a probe tip, the probe body comprising a first end portion, a second end portion, a longitudinal portion extending from the first end portion to the second end portion along a longitudinal axis, and a probe tip seat having a top surface, the longitudinal portion having a first surface facing toward a first direction substantially perpendicular to the longitudinal axis and a second surface facing toward a second direction opposite to the first direction, the probe tip extending from a part of the top surface of the probe tip seat of the probe body toward the first direction and being processed with a gradually narrowing shape by laser cutting in a way that the probe tip has a pinpoint, and a slot is formed on the top surface of the probe tip seat adjacent to the probe tip, at least one of the first end portion and the second end portion having a supporting seat protruding from the second surface toward the second direction, the supporting seat being connected to the probe installation surface of the circuit board in a way that the longitudinal portion and the probe tip are suspended above the probe installation surface.

2. The probe module as claimed in claim 1, wherein the slot is formed around a bottom surface of the probe tip.

3. The probe module as claimed in claim 1, wherein the probe tip is substantially shaped as one of a cone and a polygonal pyramid.

4. The probe module as claimed in claim 1, wherein the first end portion has said supporting seat; the second end portion is suspended above the probe installation surface; the probe tip extends from the second end portion toward the first direction; the second end portion has the probe tip seat protruding from the first surface toward the first direction.

5. The probe module as claimed in claim 1, wherein the first end portion has said supporting seat; the second end portion is suspended above the probe installation surface; the probe tip extends from the second end portion toward the first direction; the probe module comprises a plurality of said microelectromechanical probes; the microelectromechanical probes comprise a first probe and a second probe; the probe tip of the first probe and the probe tip of the second probe are located adjacent to each other and substantially aligned along an imaginary straight line; the longitudinal portion of the first probe extends from the second end portion toward a third direction substantially perpendicular to the imaginary straight line; the longitudinal portion of the second probe extends from the second end portion toward a fourth direction opposite to the third direction.

6. The probe module as claimed in claim 5, wherein the second end portion of the first probe and the second end portion of the second probe each have a connecting section directly connected with the probe tip and two concaves located by two sides of the connecting section respectively; the connecting section of the first probe is partially located in one of the concaves of the second probe; the connecting section of the second probe is partially located in one of the concaves of the first probe.

7. The probe module as claimed in claim 5, wherein the probe module comprises a probe set unit which comprises one said first probe and one said second probe; the second end portion of the first probe and the second end portion of the second probe are combined together and insulated from each other by an insulating layer.

8. The probe module as claimed in claim 7, wherein the second end portion of the first probe and the second end portion of the second probe are shaped identically and each have a protrusion substantially protruding along the longitudinal axis and a recess located adjacent to the protrusion; the probe tip of the first probe and the probe tip of the second probe are located on the protrusions respectively; the protrusion of the first probe is disposed in the recess of the second probe and insulated from the second probe by the insulating layer; the protrusion of the second probe is disposed in the recess of the first probe and insulated from the first probe by the insulating layer.

9. The probe module as claimed in claim 7, wherein the microelectromechanical probes further comprise a third probe; the probe set unit further comprises one said third probe; the probe tip of the third probe and the probe tip of the second probe are located adjacent to each other and substantially aligned along the imaginary straight line; the second end portion of the third probe and the second end portion of the second probe are combined together and insulated from each other by the insulating layer; the first end portion, the second end portion and the longitudinal portion of the third probe are combined with the first end portion, the second end portion and the longitudinal portion of the first probe respectively and insulated from the first probe by the insulating layer.

10. The probe module as claimed in claim 9, wherein the second end portion of the first probe and the second end portion of the third probe are shaped symmetrically to each other and each have a protrusion substantially protruding along the longitudinal axis and a recess located adjacent to the protrusion; the second probe has a protrusion substantially protruding along the longitudinal axis; the probe tip of the first probe, the probe tip of the second probe and the probe tip of the third probe are located on the protrusions respectively; the recess of the first probe and the recess of the third probe collectively form a concave; the protrusion of the second probe is disposed in the concave and insulated from the first probe and the third probe by the insulating layer.

11. The probe module as claimed in claim 7, wherein the probe module comprises two said probe set units which are combined together and insulated from each other by another insulating layer.

12. The probe module as claimed in claim 1, wherein the first end portion and the second end portion each have said supporting seat; the probe tip is located between the first end portion and the second end portion; the probe tip seat extends from the first surface of the longitudinal portion toward the first direction.

13. The probe module as claimed in claim 1, wherein the probe module comprises a plurality of said microelectromechanical probes; the probe tip of each of the microelectromechanical probes has a bottom surface provided opposite to the pinpoint; for one of the microelectromechanical probes, a projection of the pinpoint of the probe tip is located at a center of the bottom surface of the probe tip; for another of the microelectromechanical probes, a projection of the pinpoint of the probe tip is deviated from a center of the bottom surface of the probe tip.

14. A method of manufacturing the probe module as claimed in claim 1, which comprises the steps of:
a) forming at least one needle on the probe installation surface of the circuit board by the microelectromechanical manufacturing process in a way that the needle comprises the probe body and a processing reserved portion extending from a part of the top surface of the probe tip seat of the probe body toward the first direction;
b) defining a pinpoint position on the processing reserved portion; and
c) processing the processing reserved portion into the probe tip by laser cutting in a way that the pinpoint of the probe tip is located at the pinpoint position and the slot is formed on the top surface of the probe tip seat adjacent to the probe tip.

15. The method as claimed in claim 14, wherein in the step c) the slot is formed around a bottom surface of the probe tip.

16. The method as claimed in claim 14, wherein the processing reserved portion is substantially shaped as one of a circular cylinder, an elliptic cylinder and a polygonal cylinder.

17. The method as claimed in claim 14, wherein the processing reserved portion extends from the probe tip seat toward the first direction in a way that the processing reserved portion and the probe tip seat are continuous in shape.

18. The method as claimed in claim 14, wherein:
in the step a), a plurality of said needles are formed in a way that the longitudinal axes of the needles are substantially parallel to each other;
in the step b), an imaginary straight line is defined in a way that the processing reserved portions of the needles are aligned along the imaginary straight line, then one of the needles is chosen to serve as a reference needle which is defined on the processing reserved portion thereof with a reference origin located on the imaginary straight line and defined as the pinpoint position of the reference needle, and then the pinpoint position of each remainder said needle is defined on the imaginary straight line in an absolute coordinate manner according to the reference origin;
in the step c), the processing reserved portions of the needles are processed into the probe tips of the needles by the laser cutting in a way that the pinpoints of the probe tips are located at the pinpoint positions respectively.

19. The method as claimed in claim 18, wherein in the step b), the needles are defined according to aligned order thereof with ordinal numbers from 1 to n; in a condition that n is an odd number, the reference needle is the needle defined with the ordinal number
$$\frac{n + 1}{2} ;$$
in another condition that n is an even number, the reference needle is one of the needle defined with the ordinal number
$$\frac{n}{2}$$
and the needle defined with the ordinal number
$$\frac{n}{2} + 1 .$$

20. The method as claimed in claim 18, wherein in the step b), a top surface of the processing reserved portion of each of the needles is defined with a central point; the pinpoint position of at least one of the needles is deviated from the central point of the top surface of the processing reserved portion thereof; the farther the needle is distanced from the reference needle, the farther the pinpoint position thereof is deviated from the central point of the top surface of the processing reserved portion thereof.
